(19) United States
(12) Patent Application Publication
(10) Pub. No.: US 2026/0298540 A1
(43) Pub. Date: Oct. 1, 2026

(54) HEAT TREATMENT APPARATUS AND HEAT TREATMENT METHOD

(71) Applicant: Tokyo Electron Limited, Tokyo (JP)

(72) Inventors: Hibiki OTANI, Kumamoto (JP); Kazuhiko OOSHIMA, Kumamoto (JP); Taro YAMAMOTO, Kumamoto (JP)

(21) Appl. No.: 19/577,878

(22) Filed: Mar. 25, 2026

(30) Foreign Application Priority Data
Mar. 27, 2025 (JP) 2025-054134

(51) Int. Cl. F27B 17/00; F27D 7/02; G03F 7/16

(52) U.S. Cl. CPC F27B 17/0025; F27D 7/02; G03F 7/168; F27D 2007/023

(57) ABSTRACT

A heat treatment apparatus includes a processing container having a processing space formed therein, a stage on which a substrate is placed to face the processing space, a heating unit that heats the substrate placed on the stage, a discharge port that is open to the processing space and discharges a processing gas to the heated substrate, and a mixing section that forms a gas supply path connected to the discharge port and mixes gases such that two or more types of processing gases and a carrier gas for each of the processing gases are brought into a mixed state.

### CROSS REFERENCES TO RELATED APPLICATIONS

This application is based on and claims priority from Japanese Patent Application No. 2025-054134, filed on March 27, 2025, with the Japan Patent Office, the disclosure of which is incorporated herein in its entirety by reference.

### TECHNICAL FIELD

The present disclosure relates to a heat treatment apparatus and a heat treatment method.

### BACKGROUND

In a manufacturing process of a semiconductor device, various liquid processings and heat treatments are performed on a substrate such as a semiconductor wafer (hereinafter referred to as "wafer"). In some cases, the heat treatment is performed while supplying a gas to the wafer. Japanese Patent Laid-open Publication No. 2000-058407 discloses an apparatus that performs heating a substrate after application of a resist solution to remove a solvent in the solution, by supplying two types of gases.

### SUMMARY

A heat treatment apparatus of the present disclosure includes a processing container having a processing space formed therein, a stage on which a substrate is placed to face the processing space, a heating unit that heats the substrate placed on the stage, a discharge port that is opened to the processing space and discharges a processing gas to the heated substrate, and a mixing section that forms a gas supply path connected to the discharge port and mixes gases such that two or more types of processing gases and a carrier gas for each of the processing gases are brought into a mixed state.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view of a system according to an embodiment, which is a substrate processing apparatus of the present disclosure.

FIG. 2 is a front view of the system, according to an embodiment of the present disclosure.

FIG. 3 is a plan view illustrating a portion of the system.

FIG. 4 is a longitudinal sectional side view of a heat treatment apparatus provided in the system.

FIG. 5 is a longitudinal sectional side view illustrating a processing container provided in the heat treatment apparatus.

FIG. 6 is a transverse sectional view of the processing container as viewed from below.

FIG. 7 is a transverse sectional view of the processing container as viewed from above.

FIG. 8 is an explanatory diagram illustrating mixing of gases.

FIG. 9 is a longitudinal sectional side view of the heat treatment apparatus illustrating an operation example of the apparatus.

FIG. 10 is a longitudinal sectional side view of the heat treatment apparatus illustrating the operation example of the apparatus.

FIG. 11 is a longitudinal sectional side view of the heat treatment apparatus illustrating another operation example of the apparatus.

FIG. 12 is a longitudinal sectional side view of the heat treatment apparatus illustrating still another operation example of the apparatus.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, a wafer processing system serving as a substrate processing apparatus according to the present embodiment will be described with reference to the drawings. In addition, in this specification, elements having substantially the same functional configuration will be denoted by the same reference numerals, and redundant descriptions thereof will be omitted.

### Wafer Processing System

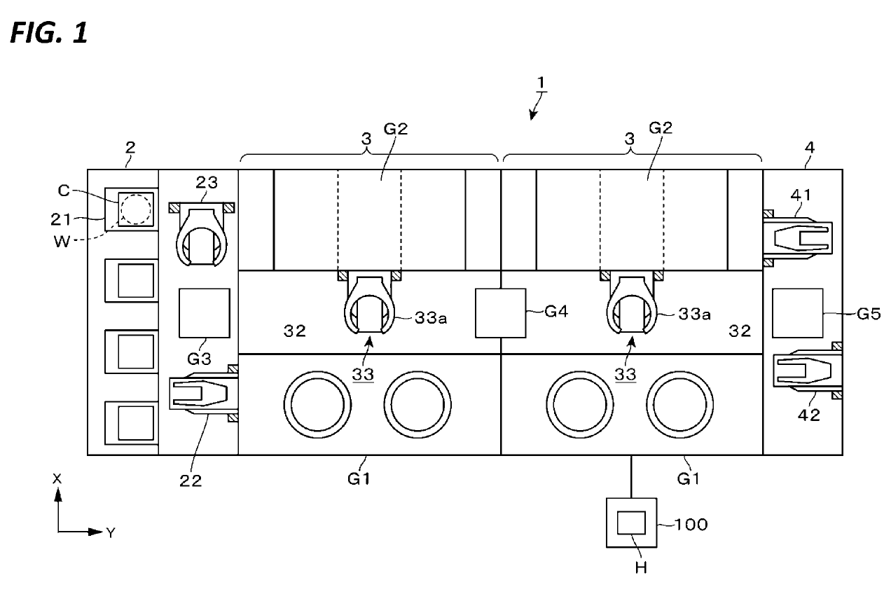

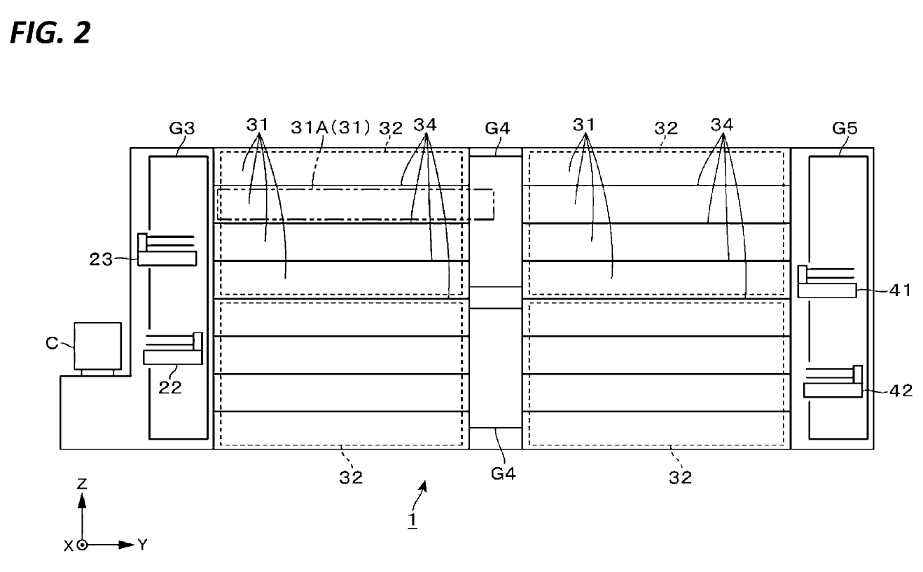

First, a configuration of the wafer processing system according to the present embodiment will be described. FIGS. 1 and 2 are a plan view and a front view, respectively, schematically illustrating the outline of a configuration of a wafer processing system 1. In the present embodiment, a case where the wafer processing system 1 is a photolithography processing system that performs a resist film formation processing and a development processing on a wafer W will be described by way of example.

As illustrated in FIG. 1, the wafer processing system 1 includes a cassette station 2 into and from which a cassette C accommodating a plurality of wafers W is loaded and unloaded, and a processing station 3 including a plurality of various processing apparatuses each configured to perform a predetermined processing on the wafer W. Then, the wafer processing system 1 has a configuration in which the cassette station 2, the processing station 3, and an interface station 4 are integrally connected. The interface station 4 is configured to transfer the wafer W between the processing station 3 and an exposure apparatus (not illustrated) that is adjacent to the interface station 4 on a side opposite to the processing station 3. In addition, although two processing stations 3 are provided between the cassette station 2 and the interface station 4 as illustrated in FIG. 1, only one processing station may be provided, or three or more processing stations may be provided.

The cassette station 2 is provided with a plurality of cassette placement tables 21 and wafer transport devices 22 and 23. The cassette station 2 transports the wafer between the cassette C placed on the cassette placement table 21 and the processing station 3 by the wafer transport device 22 or 23. Therefore, each of the wafer transport devices 22 and 23 may include, as necessary, drive mechanisms having movement paths in respective directions such as the horizontal direction (X-direction and Y-direction), the vertical direction (Z-direction), and the rotational direction around a vertical axis (θ direction), or may include a drive mechanism having movement paths in all of these directions.

At least one of the wafer transport devices 22 and 23 is capable of transferring the wafer to and from the cassette C, and is also capable of transferring the wafer to and from the processing station 3. In addition, a wafer transfer operation to and from the processing station 3 refers, for example, to transferring the wafer to and from a third block G3 including a transfer device accessible by a wafer transport device 33 in the processing station 3, which will be described later. The third block G3 may include a plurality of transfer devices (not illustrated) arranged in the vertical direction.

In addition, an inspection apparatus (not illustrated) configured to inspect the wafer W may be provided at a position accessible by either of the wafer transport devices 22 and 23.

The processing station 3 is provided with a plurality of blocks, for example, three blocks G1, G2, and G4 corresponding to a first block, a second block, and a fourth block. Further, as illustrated in FIG. 2, a plurality of layers 31 each including the first block G1 and the second block G2 are stacked in the vertical direction. For example, the first block G1 is provided on a front side of the processing station 3 (e.g., a negative X-direction side in FIG. 1), and the second block G2 is provided on a rear side of the processing station 3 (e.g., a positive X-direction side in FIG. 1). The fourth block G4 is provided at an interface station 4 side of the processing station 3 (e.g., a positive Y-direction side in FIG. 1) or at a connection portion with another adjacent processing station 3. The fourth block G4 may include a plurality of transfer devices arranged in the vertical direction. Further, the above-described third block G3 may also be provided in the processing station 3.

In the first block G1, a plurality of processing apparatuses, for example, patterning film forming apparatuses and a developing apparatus, all of which are not illustrated, are arranged. The patterning film forming apparatuses may include, for example, a resist film forming apparatus and an anti-reflection film forming apparatus. For example, the plurality of processing apparatuses are arranged side by side in the horizontal direction. In addition, the number, arrangement, and types of these processing apparatuses may be selected arbitrarily.

The patterning film forming apparatuses and the developing apparatus perform, for example, the supply of a predetermined processing liquid or the supply of a predetermined gas onto the wafer W. In this way, the patterning film forming apparatuses perform, for example, formation of a resist film to be used as a mask for forming a pattern on an underlying film and formation of an anti-reflection film for efficiently performing a light irradiation processing such as an exposure processing. Further, on the other hand, the developing apparatus removes a portion of the exposed resist film to form an uneven shape serving as the mask.

For example, in the second block G2, heat treatment apparatuses (not illustrated) that perform a heat treatment such as heating and cooling of the wafer W are arranged side by side in the vertical direction and the horizontal direction. Further, in the second block G2, although not illustrated, a hydrophobization treatment apparatus that performs a hydrophobization treatment to increase adhesion between a resist solution and the wafer W and a peripheral exposure apparatus that exposes the outer periphery of the wafer W are arranged side by side in the vertical direction (e.g., Z-direction in FIG. 2) and the horizontal direction. The number and arrangement of these heat treatment apparatuses, hydrophobization treatment apparatus, and peripheral exposure apparatus may be selected arbitrarily.

As illustrated in FIG. 1, in a plan view, a wafer transport region 32 is formed in a region sandwiched between the first block G1 and the second block G2. For example, the wafer transport device 33 is disposed in the wafer transport region 32.

The wafer transport device 33 includes, for example, a transport arm 33a, which is movable in the Y direction, the front-rear direction, the θ direction, and the vertical direction. The wafer transport device 33 may move in the wafer transport region 32 to transport the wafer W to predetermined apparatuses in the surrounding first block G1, second block G2, third block G3, and fourth block G4. When a plurality of processing stations 3 are provided as illustrated in FIG. 1, the wafer transport device 33 provided in the processing station 3 located on the interface station 4 side may transport the wafer W not only to the first, second, and fourth blocks G1, G2, and G4 but also to predetermined apparatuses in a fifth block G5, which will be described later.

For example, as illustrated in FIG. 2, a plurality of wafer transport devices 33 are arranged vertically. One wafer transport device 33 may transport the wafer W to predetermined apparatuses located at heights corresponding to a plurality of upper layers 31 among the plurality of vertically stacked layers 31. Another wafer transport device 33 may transport the wafer W to predetermined apparatuses located at heights corresponding to a plurality of lower layers 31 below the upper layers 31. A plurality of wafer transport regions 32 are provided to enable such transport of the wafer W. In addition, the number of wafer transport devices 33 and the number of layers 31 corresponding to a single wafer transport device 33 may be selected arbitrarily, for example, such that one wafer transport device 33 is provided for each layer 31.

Further, a shuttle transport device (not illustrated) may be provided in the wafer transport region 32, in the first block G1, or in the second block G2. The shuttle transport device linearly transports the wafer W between a space adjacent to one side of the processing station 3 and another space adjacent to the opposite side thereof.

The interface station 4 is provided with the fifth block G5 including a plurality of transfer devices, and wafer transport devices 41 and 42. The interface station 4 transports the wafer W between the fifth block G5, to and from which the wafer W is transferred by the wafer transport device 33, and the exposure apparatus, by using the wafer transport device 41 or 42. Therefore, each of the wafer transport devices 41 and 42 may include, as necessary, drive mechanisms having movement paths in respective directions such as the horizontal direction (e.g., X-direction and Y-direction), the vertical direction (e.g., Z-direction), and the rotational direction around a vertical axis (θ direction), or may include a drive mechanism having movement paths in all of these directions. At least one of the wafer transport devices 41 and 42 may support the wafer W and transport the wafer W between the exposure apparatus and the transfer devices in the fifth block G5.

A cleaning apparatus configured to clean a surface of the wafer W and the above-described peripheral exposure apparatus may be provided in the interface station 4 at positions accessible by either of the wafer transport devices 41 and 42.

The inspection apparatus may be provided in the cassette station 2 as described above, but may also be provided in the processing station 3 and the interface station 4 at positions accessible by either of transport arms (33, 41, and 42 in FIGS. 1-2) provided in the interior of the respective stations.

The wafer processing system 1 described above is provided with a control device 100 serving as a controller. The control device 100 is, for example, a computer having a program storage (not illustrated). The program storage stores programs for controlling processing of the wafer W in the wafer processing system 1. Further, the program storage also stores programs for controlling operations of drive systems of the above-described various processing apparatuses and transport devices so as to realize wafer processing in the wafer processing system 1. The programs include a group of steps necessary for executing the transport and processing of the wafer W in the wafer processing system 1, and the control device 100 outputs control signals to respective parts of the wafer processing system 1 based on the programs, and controls the respective parts as described above to perform the transport and processing of the wafer W. In addition, the programs may be recorded in a computer-readable storage medium H and installed into the control device 100 from the storage medium H. The storage medium H may include, for example, a ROM, a RAM, and a hard disk, but is not limited in structure or type, and may be either a temporary or non-temporary medium. In addition, the control device 100 may include portions that perform recording, reading, and execution of the programs for realizing wafer processing, as well as communication related thereto, and each portion may be placed either inside or outside the wafer processing system 1. The control device 100 may include one or a plurality of circuits, and may be provided integrally or separately in part.

### Operation of Wafer Processing System

The wafer processing system 1 is configured as described above. Next, an example of wafer processing performed using the wafer processing system 1 configured as described above will be described.

First, the cassette C accommodating the plurality of wafers W is loaded into the cassette station 2 of the wafer processing system 1 and is placed on the cassette placement table 21. Next, the respective wafers W in the cassette C are sequentially taken out by the wafer transport device 22 or 23 and are transported to the transfer device of the third block G3.

The wafer W transported to the transfer device of the third block G3 is supported by the wafer transport device 33 and is transported to the hydrophobization treatment apparatus provided in the second block G2, in which a hydrophobization treatment is performed. Next, the wafer W is transported by the wafer transport device 33 to a resist film forming apparatus in which a resist film is formed on the wafer W, and then transported to a heat treatment apparatus and subjected to a prebake processing, and then transported to the transfer device of the fifth block G5. In addition, when a plurality of processing stations 3 are provided as illustrated in FIGS. 1 and 2, the wafer W is placed once on the transfer device of the fourth block G4 before being transported to the transfer device of the fifth block G5, and is then transferred to and from a plurality of wafer transport devices 33. Further, the wafer W may also be transported by the wafer transport device 33 to the peripheral exposure apparatus as necessary, in which an exposure processing may be performed on a peripheral edge portion of the wafer.

The wafer W transported to the transfer device of the fifth block G5 is transported by the wafer transport devices 41 and 42 to the exposure apparatus and is subjected to an exposure processing in accordance with a predetermined pattern. In addition, the wafer W may be cleaned by the cleaning apparatus before the exposure processing.

The exposed wafer W is transported by the wafer transport devices 41 and 42 to the transfer device of the fifth block G5. Thereafter, the wafer W is transported by the wafer transport device 33 to the heat treatment apparatus and is subjected to a post-exposure bake processing.

The wafer W, subjected to the post-exposure bake processing, is transported by the wafer transport device 33 to the developing apparatus, in which the wafer is developed. After completion of development, the wafer W is transported by the wafer transport device 33 to the heat treatment apparatus and is subjected to a post-bake processing.

Thereafter, the wafer W is transported by the wafer transport device 33 to the transfer device of the third block G3, and is transported by the wafer transport device 22 or 23 of the cassette station 2 to the cassette C on a predetermined cassette placement table 21. In this way, a series of photolithography processes is completed.

In addition, the wafer processing system according to the present disclosure is not limited to the configuration and operation described above. For example, although the wafer processing system is directly connected to the exposure apparatus and transfers the wafer W between the interface station 4 and the exposure apparatus in the above embodiment, the wafer processing system may not be directly connected to the exposure apparatus. In such a case, for example, after the wafer W is transported from the cassette station 2 to the processing station 3 and is subjected to a necessary processing, the wafer W may be transported again to the cassette station 2 so as to be unloaded out of the system. Further, among the processing apparatuses described above, apparatuses that are not required may be omitted from the wafer processing system, or processing in such apparatuses may not be performed.

### Processing Station

The processing station 3 of the wafer processing system 1 will now be described in more detail. As described above, the processing station 3 is provided with a plurality of stacked layers 31 each including the second block G2, and these layers 31 are partitioned from one another, for example, by walls 34. Then, in each layer 31, the wafer W is transferred to and from the apparatuses provided in the second block G2, as described above. In addition, the wafer transport region 32 facing the second block G2 may or may not be partitioned for each layer 31. Accordingly, the above-described wafer transport device 33 may be shared by the plurality of layers 31, and may move between the plurality of layers 31 to transfer the wafer W to and from the apparatuses in the second block G2 of each layer 31. Alternatively, the wafer transport device 33 may be provided for each layer 31 to transfer the wafer W to and from the apparatuses in the second block G2 of each layer 31.

Any one of the plurality of layers 31 is designated as a layer 31A. In FIG. 2, the layer 31A is illustrated as the second layer counted from the top, but the layer 31A is not limited to that specific level, and any one of the layers 31 may be designated as the layer 31A. Further, in FIG. 2, the layer 31A is illustrated as being located in the processing station 3 on the cassette station 2 side among the processing stations 3 arranged in the Y-direction, but the layer 31A may instead be located in the processing station 3 on the interface station side.

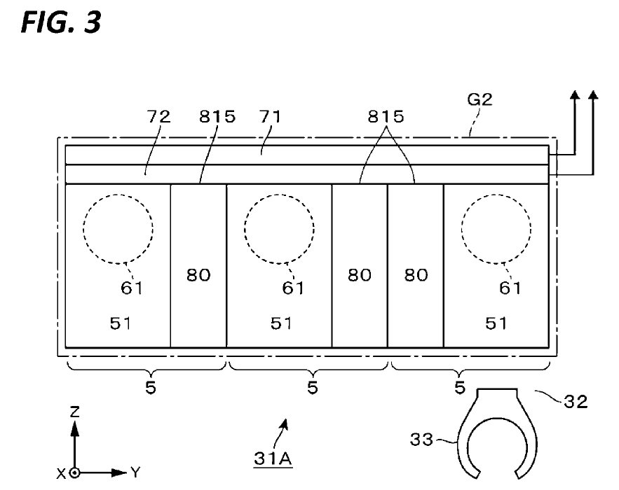

A plan view of the second block G2 in the layer 31A is illustrated in FIG. 3. The second block G2 of the layer 31A is provided with a plurality of heat treatment apparatuses 5, and these heat treatment apparatuses 5 are arranged side by side in the Y-direction, which is the longitudinal direction of the wafer transport region 32. Each heat treatment apparatus 5 includes a case 51 having therein a processing container 61 configured to accommodate and process the wafer W, and a first gas supply unit 80. Although a configuration of the first gas supply unit 80 will be described in detail later, the first gas supply unit 80 briefly includes a box 815 that internally accommodates portions of supply paths for supplying gases into the processing container 61, including devices such as valves, and portions where different types of gases are mixed, and the inside of the box 815 is exhausted. The heat treatment apparatus 5 is capable of supplying gases mixed by the first gas supply unit 80 to the processing container 61 in the case 51.

The case 51 and the first gas supply unit 80, which constitute the same heat treatment apparatus 5, are adjacent to each other in the Y-direction, and no case 51 and/or first gas supply unit 80 of another heat treatment apparatus 5 is positioned between the case 51 and the first gas supply unit 80 constituting the same heat treatment apparatus 5. In addition, in arranging the case 51 and the first gas supply unit 80 of each heat treatment apparatus 5 in the second block G2 in such a layout, when the Y-direction is regarded as the left-right direction, FIG. 3 illustrates an example in which different heat treatment apparatuses 5 have different left-right arrangements of the case 51 and the first gas supply unit 80. That is, in one heat treatment apparatus 5, the case 51 is positioned on the right side, whereas in another heat treatment apparatus 5, the first gas supply unit 80 is positioned on the right side. However, the left-right arrangement of the case 51 and the first gas supply unit 80 may be not different between the heat treatment apparatuses 5, and may be the same for all of the heat treatment apparatuses 5.

Then, the wafer processing system 1 includes a first exhaust duct 71, a second exhaust duct 72, a third exhaust duct 73, and an exhaust duct 816, and these exhaust ducts extend in parallel with one another in the Y-direction and are connected to respective locations of the respective heat treatment apparatuses 5, which will be described later. In FIG. 3, only the first exhaust duct 71 and the second exhaust duct 72 are illustrated representatively among these exhaust ducts. Exhaust downstream sides of the first exhaust duct 71, the second exhaust duct 72, the third exhaust duct 73, and the exhaust duct 816 are connected to an exhaust source (not illustrated). The exhaust source may be, for example, a relatively low-pressure exhaust path provided as facility equipment of a factory in which the wafer processing system 1 is installed, and may include an exhaust mechanism such as a fan.

By the exhaust source, exhaust is performed from inside each exhaust duct toward the exhaust source as indicated by arrows in the drawings. More specifically, gases in spaces of respective parts of the heat treatment apparatus 5, communicating with the respective exhaust ducts, are discharged to flow into the corresponding exhaust ducts and be directed toward the exhaust source. Exhaust of the respective parts of the heat treatment apparatus 5 through the first exhaust duct 71, the second exhaust duct 72, the third exhaust duct 73, and the exhaust duct 816 is performed, for example, continuously while the heat treatment apparatus 5 is in operation. The exhaust source serving as an exhaust destination may be the same or different between the first exhaust duct 71, the second exhaust duct 72, the third exhaust duct 73, and the exhaust duct 816.

As described above, the first exhaust duct 71, the second exhaust duct 72, the third exhaust duct 73, and the exhaust duct 816 are provided in the wafer processing system 1 as members arranged outside the respective heat treatment apparatuses 5, so as to be shared by the respective heat treatment apparatuses 5 provided in the layer 31A. In addition, the number of heat treatment apparatuses 5 provided in the layer 31A is not limited to the number (three) illustrated in FIG. 3.

### Heat Treatment Apparatus

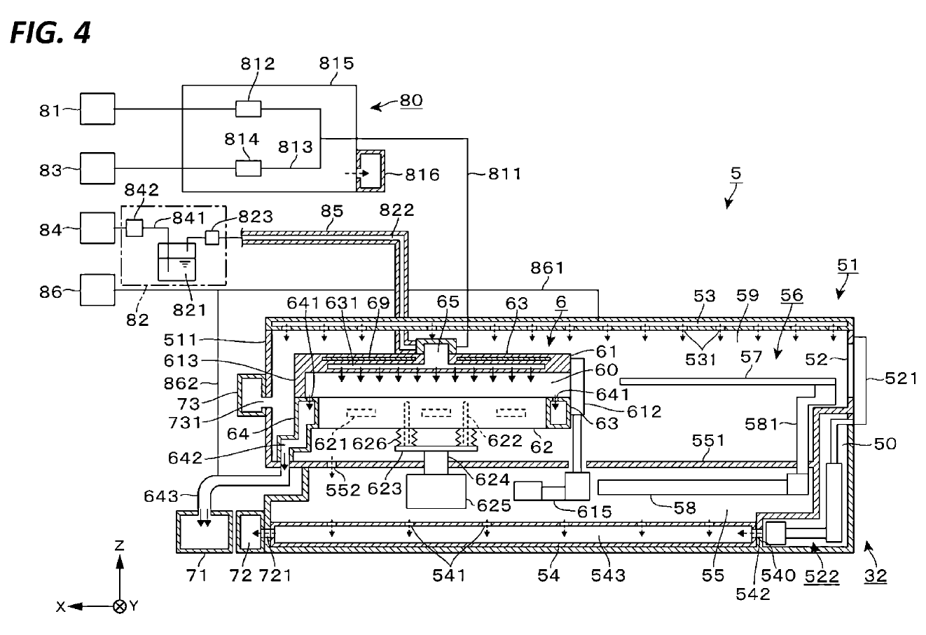

An embodiment of the heat treatment apparatus 5 will be described with reference to FIG. 4, which is a longitudinal sectional side view. In FIG. 4, the flow of a processing gas formed in the apparatus is indicated by solid arrows, and the flow of a dilution gas, which will be described later, is indicated by dashed arrows. The heat treatment apparatus 5 heats the wafer W having a film such as a resist film formed on a surface (e.g., upper surface) thereof while supplying a processing gas to the wafer W. Thus, for example, processing such as film modification is performed by causing a predetermined reaction to proceed in the film through the action of the processing gas.

As described above, the heat treatment apparatus 5 includes the case 51. A heat treatment section 6 configured to perform a heat treatment on the wafer W and a temperature control unit 56 configured to adjust the temperature of the wafer W are arranged side by side in the front-rear direction (e.g., X-direction) in the inside of the case 51, with the temperature control unit 56 positioned at the front side. A loading/unloading port 52 for the wafer W is formed on a side surface of the case 51 toward the wafer transport region 32, and the wafer W is transferred to and from the wafer transport device 33 through the loading/unloading port 52.

A shutter 521 is provided on a front side of the case 51. The shutter 521 is configured to be movable in the front-rear direction and in the vertical direction by a drive mechanism 522, thereby moving in the same manner as a shutter 612 provided in the processing container 61, which will be described later, so as to open and close the loading/unloading port 52. The shutter 521 closes the loading/unloading port 52 at least while the processing gas is supplied into the processing container 61 to be described later so as to seal the inside of the case 51, thereby suppressing leakage of the processing gas into the wafer transport region 32. For example, the drive mechanism 522 is disposed in a region 50 partitioned from a region in which the heat treatment section 6 is provided in the case 51, and the region 50 is located on a lower side in the case 51. An exhaust chamber 55 is provided in the lower side of the case 51, in addition to the region 50. Then, a gas supply chamber 53 is provided in a ceiling wall of the case 51. The ceiling wall and the exhaust chamber 55 will be described in detail later.

### Heat Treatment Section

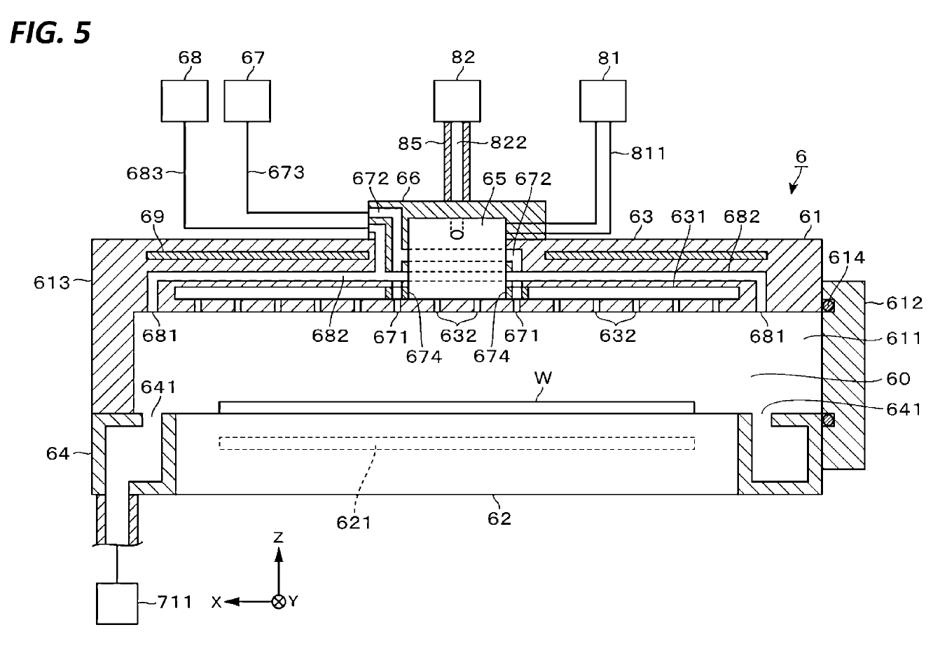

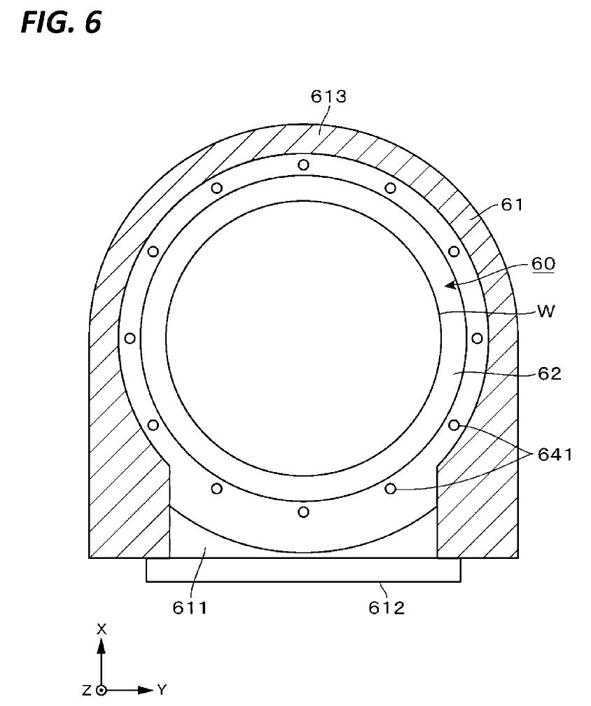

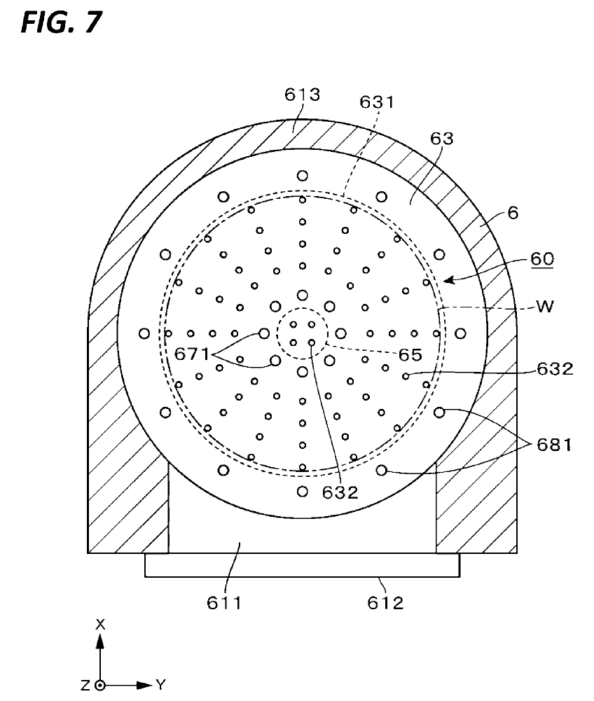

Next, a configuration example of the heat treatment section 6 will be described with reference to FIGS. 5-7. FIG. 5 is a longitudinal sectional side view of the heat treatment section 6, and the heat treatment section 6 includes the processing container 61 that defines a processing space 60 for accommodating the wafer W. During processing of the wafer W, the processing space 60 is maintained as an airtight space. FIG. 6 is a transverse sectional view of the processing container 61 as viewed from the processing space 60 toward the lower side, and FIG. 7 is a transverse sectional view as viewed from the processing space 60 toward the upper side.

As illustrated in these drawings, an opening 611 for loading and unloading the wafer W into and out of the processing space 60 is formed in a sidewall of the processing container 61 on the temperature control unit 56 side, and the opening 611 is configured to be opened and closed by the shutter 612 serving as a lid. The processing container 61 is constituted by combining, in the front-rear direction, a cylindrical region having a sidewall 613 surrounding the wafer W laterally and a short rectangular region in the front-rear direction that forms the opening 611. In this example, a bottom wall of the processing container 61 is configured as a hot plate 62 provided so as to be horizontal, and a ceiling plate 63 of the processing container 61 is configured to have gas discharge ports 632 and exhaust ports 671 and 681. In addition, in FIG. 4, illustration of the discharge ports 632 and the exhaust ports 671 and 681 is omitted.

First, the lower side of the processing container 61 will be described with reference to FIGS. 4-6. The hot plate 62, which serves as a stage for the wafer W, has a disk shape, and an upper surface thereof forms a placement surface for the wafer W. The wafer W is placed in a placement region on the hot plate 62 such that the surface (e.g., upper surface) thereof faces the processing space 60. FIGS. 6 and 7 illustrate the wafer W placed on the hot plate 62, and the placement region includes a central portion of the hot plate 62 and is a circular region centered on the center of the hot plate 62 in a plan view.

A heater 621, which is a heating unit such as a resistance heating heater, is incorporated in the hot plate 62 (see, e.g., FIG. 4), and heats the wafer W placed in the placement region to a predetermined temperature. Further, a lifting pin 622 for transferring the wafer W is provided in the hot plate 62 so as to be raised and lowered by a drive mechanism 625 via a lifting plate 623 and a lifting shaft 624. The lifting plate 623 is provided below the hot plate 62 and above a partition plate 551, which will be described later. Then, in order to maintain airtightness of the processing space 60, a vertically expandable and contractible bellows 626 is provided around the lifting pin 622 to connect the lifting plate 623 to a lower surface of the hot plate 62.

An exhaust unit 64 is provided around the hot plate 62 to surround the hot plate 62 in the circumferential direction. The exhaust unit 64 includes, for example, an annular body having a rectangular longitudinal cross section, and an upper surface thereof is, for example, flush with the upper surface of the hot plate 62. Then, a plurality of exhaust ports 641 are formed at intervals on the upper surface of the exhaust unit 64 along the circumference of the hot plate 62 ( e.g., along the circumference of the wafer W on the hot plate 62). As such, the exhaust ports 641 are provided laterally with respect to the placement region of the wafer W on the hot plate 62 ( e.g., at positions not overlapping the placement region in a plan view), and each exhaust port 641 opens upward to face the processing space 60. In addition, instead of providing the plurality of exhaust ports 641 at intervals as described above, an annular slit may be formed along the circumference of the hot plate 62. Further, a lower end of the sidewall 613 of the processing container 61 is connected to the upper surface of the exhaust unit 64 outside a region in which the exhaust ports 641 are formed.

An exhaust path 640 communicating with the respective exhaust ports 641 is formed in an annular shape in the inside of the exhaust unit 64, so as to surround the hot plate 62. The above-described first exhaust duct 71 is provided at a rear position with respect to the case 51, for example, at a height corresponding to a lower end of the case 51, and an exhaust path forming member 643 that connects the first exhaust duct 71 to a lower surface on a rear side of the exhaust unit 64 is formed so as to penetrate a wall portion of the case 51 and extend from inside to outside of the case 51. An exhaust path 642 connecting the exhaust path 640 and the inside of the first exhaust duct 71 is provided in the exhaust path forming member 643, and a gas in the processing space 60 flows through the exhaust ports 641 of the exhaust unit 64, the exhaust path 642, and the first exhaust duct 71 in this order and is discharged. Exhaust of the processing space 60 through the exhaust ports 641 is, for example, performed continuously while the heat treatment apparatus 5 is in operation. The wafer W is processed, for example, in a state where the processing space 60 is at a pressure within a low vacuum range lower than atmospheric pressure by this exhaust and gas supply to the processing space 60, which will be described later.

Next, the ceiling plate 63 of the processing container 61 will be described with reference to FIGS. 4, 5, and 7. The ceiling plate 63 constitutes a ceiling portion of the processing container 61 and is formed to be horizontal. A flat diffusion space 631 is provided in a region facing the hot plate 62 in the ceiling plate 63. The diffusion space 631 is formed larger than the wafer W placed in the placement region on the hot plate 62 in a plan view. A lower surface of the ceiling plate 63 faces the placement region of the hot plate 62. Then, a large number of gas discharge ports 632, each communicating with the diffusion space 631, are formed so as to be dispersed over a portion of the lower surface facing the placement region and to open downward. Furthermore, a heating unit 69 for heating the ceiling plate 63 is incorporated, for example, above the diffusion space 631 in the top plate 63. Thereby, even when a gas that is easily liquefied at room temperature is used, liquefaction may be suppressed and the gas may be discharged into the processing space 60 through the discharge ports 632.

Further, a mixing section 65 is provided above a central portion of the diffusion space 631 so as to be connected to the diffusion space 631. The mixing section 65 is a space in which a plurality of gases are mixed and constitutes a gas supply path toward the discharge ports 632 in conjunction with the diffusion space 631. Accordingly, the mixing section 65 is a space positioned directly above the diffusion space 631. In this example, a protrusion 66 is provided at a central portion of the ceiling plate 63, and the mixing section 65 is formed by an internal space of the protrusion 66 and a space provided in the ceiling plate 63. As illustrated in FIG. 7, each of the mixing section 65 and the diffusion space 631 is a circular space in a plan view, the center of which coincides with the center of the placement region of the wafer W, and a diameter of the mixing section 65 is smaller than a diameter of the diffusion space 631.

A first processing gas and a second processing gas, which serve as a processing gas, and a carrier gas for the processing gas are supplied to the mixing section 65. As the first processing gas and the second processing gas, gases having a stronger effect on the quality of a film formed on the wafer W than the carrier gas are used, such as an oxygen (O₂) gas, carbon dioxide (CO₂) gas, ammonia (NH₃) gas, carboxylic acid gas such as acetic acid (CH₃COOH), and water (H₂O) (water vapor). In the heat treatment apparatus 5, a heat treatment is performed using two types of gases selected as the first processing gas and the second processing gas from among the gas group of gases listed above. Accordingly, in the mixing section 65 constituting a portion of the gas supply path, different types of processing gases and the carrier gas are mixed, and the mixed gas is diffused through the diffusion space 631, distributed to the respective discharge ports 632, and discharged from the discharge ports 632 toward the wafer W heated by the hot plate 62. In this way, a gas atmosphere in which a plurality of desired processing gases are mixed is formed in the processing space 60 in which the wafer W is placed, thereby enabling heat treatment of the wafer W.

In the present embodiment, the second processing gas is described as a gas generated by vaporizing a liquid precursor. Further, as the carrier gas, an inert gas such as a nitrogen gas (N₂ gas) or argon gas (Ar gas) may be used, and in the present embodiment, the carrier gas is described as being such an inert gas.

### Supply Path of First Processing Gas

As illustrated in FIG. 4, a supply source 81 of the first processing gas is connected to the mixing section 65 of the processing container 61 via a first supply path 811 having a supply device 812. In addition, a downstream end of the first supply path 811 is connected to the mixing section 65 from a lateral side thereof. Further, a downstream end of a supply path 813 is connected to the first supply path 811 at a position downstream of the supply device 812, and an upstream end of the supply path 813 is connected to a supply source 83 of an inert gas. A supply device 814 is provided in the supply path 813. The supply devices 812 and 814, as well as other supply devices to be described later, each include, for example, a valve and a flow rate regulator, and are configured to be able to switch between supply and stoppage of a fluid to a downstream side of a flow path and to regulate a flow rate of the fluid supplied to the downstream side. Operations of the respective supply devices are independently controlled by the control device 100.

Further, since the first supply path 811 and the supply path 813 are connected to each other, when the first processing gas from the supply source 81 and the inert gas from the supply source 83 are supplied together toward the processing container 61, these gases are mixed at a connection portion between the first supply path 811 and the supply path 813 and then supplied to the processing container 61. In such mixing, the inert gas from the supply source 83 functions as a dilution gas and a carrier gas for the first processing gas. However, the first processing gas may be supplied toward the mixing section 65 without being mixed with the inert gas from the supply source 83. Then, the inert gas supplied from the supply source 83 may also be supplied to the processing space 60 through the mixing section 65 without being mixed with the first processing gas as described later, thereby functioning as a purge gas for purging the processing space 60. As described above, the first processing gas from the supply source 81 and the inert gas from the supply source 83 may be supplied to the processing container 61 in a mixed state, or may be supplied independently without being mixed.

Here, the first supply path 811 and the supply path 813 described above are flow paths formed by flow path forming members such as pipes. For example, when a combustion supporting gas such as an oxygen gas or a toxic gas such as an ammonia gas is used as the first processing gas, it is desirable that the first supply path 811 be formed of a metallic pipe such as stainless steel, that is, a rigid pipe, in consideration of gas resistance and safety. However, a connection portion between the supply path 813 and the first supply path 811 takes a configuration in which flow path forming members are connected via a joint, for example. Then, the flow path forming members forming the first supply path 811 and the supply path 813 are respectively connected to the supply devices 812 and 814 via joints. Since joints are provided at various locations in this manner, there is a risk that gases may leak from such joints.

Therefore, the box 815 as described with reference to FIG. 3 is provided, and the above-described joints are accommodated in the box 815. That is, a connection portion between the first supply path 811 and the supply path 813 and portions of the first supply path 811 and the supply path 813 provided with the supply devices 812 and 814 are accommodated in the box 815. The box 815, the portions of the first supply path 811 and the supply path 813 accommodated in the box 815, and the supply devices 812 and 814 accommodated in the box 815 constitute the first gas supply unit 80 described with reference to FIG. 3. Since the first processing gas and the inert gas are able to be mixed at a connection portion between the first supply path 811 and the supply path 813 in the box 815, the first gas supply unit 80 also functions as a gas mixer. Then, the above-described exhaust duct 816 is connected to the box 815, and an atmosphere in the box 815 is exhausted through the exhaust duct 816. With such a configuration, even if each gas leaks from the joint, diffusion of the gas to the outside of the box 815 is suppressed.

In addition, since the gases are supplied respectively from the supply sources 81 and 83 as described above, the first processing gas from the first gas supply unit 80 is supplied toward the processing container 61 either alone or in a state mixed with the inert gas. In the following description, the first processing gas supplied from the first gas supply unit 80 either alone or mixed with the inert gas may be referred to as a first gas.

Here, a positional relationship between the first gas supply unit 80 illustrated in FIG. 3 and the case 51 including therein the processing container 61 will be further described. As described above, the first gas supply unit 80 and the case 51 are located in the same layer 31A (that is, the first gas supply unit 80 and the processing container 61 are located in the same layer 31A). By arranging the first gas supply unit 80 and the case 51 in this manner, a distance from a gas mixing position (e.g., a connection portion between the first supply path 811 and the supply path 813) to the processing container 61 may be made relatively short.

Accordingly, changes in properties of the gas at the mixing position are suppressed before the gas reaches the processing container 61, and deterioration in uniformity of processing among the wafers W is suppressed. More specifically, for example, a temperature regulation mechanism such as a heater is provided to ensure that a gas temperature at the mixing position becomes a predetermined temperature. In this manner, variation in the temperature of the temperature-adjusted gas before the gas reaches the processing container 61, and variation in the temperature for each processing of the wafer W, are suppressed, and changes in reactivity of the gas are suppressed, thereby suppressing influence on processing of the wafer W.

Further, since a layout is such that no case 51 and/or first gas supply unit 80 of another heat treatment apparatus 5 is positioned between the case 51 and the first gas supply unit 80 constituting the same heat treatment apparatus 5, the distance from the mixing position to the processing container 61 may be made even shorter, which is desirable. Further, according to this layout, it is possible to suppress large differences in a length of the first supply path 811 from the case 51 to the first gas supply unit 80 between the plurality of heat treatment apparatuses 5, thereby enabling highly uniform processing of the wafer W between the plurality of heat treatment apparatuses 5.

### Supply Path of Second Processing Gas

The configuration for supplying the processing gas in the heat treatment apparatus 5 will now be described again with reference to FIG. 4 and related drawings. A liquid precursor serving as the second processing gas is accommodated in a container 821. The container 821 includes a heating unit (not illustrated) that heats the liquid precursor. Then, the container 821 is connected to a supply source 84 of an inert gas serving as a carrier gas via a supply path 841 in which a supply device 842 is interposed and the liquid precursor in the container 821 heated by the heating unit is vaporized by the supply of the inert gas from the supply source 84 to become the second processing gas. Then, the second processing gas is supplied to the mixing section 65 together with the inert gas serving as the carrier gas through a second supply path 822 in which a supply device 823 is interposed.

In addition, the second processing gas in a state mixed with the carrier gas (inert gas) supplied from the supply source 84 is referred to as a second gas. The container 821, the supply devices 842 and 823, a portion of the supply path 841 extending from the supply device 842 to the container 821, and a portion of the second supply path 822 extending from the container 821 to the supply device 842 are collectively defined as a second gas supply unit 82, which is indicated by a chain line in FIG. 4.

A heating unit 85 for heating the second supply path 822 is provided. For example, the second supply path 822 is configured with a pipe serving as a flow path forming member, and a heater provided around the pipe over the entire longitudinal length of the pipe forms the heating unit 85. Accordingly, the heating unit 85 serves as a gas heating unit for heating a portion of a processing gas supply path upstream of the mixing section 65 of the processing container 61. The second supply path 822 is heated by the heating unit 85 to a temperature at which liquefaction of the gas passing through the second supply path 822 is suppressed.

### Supplementary Description of Mixing Section

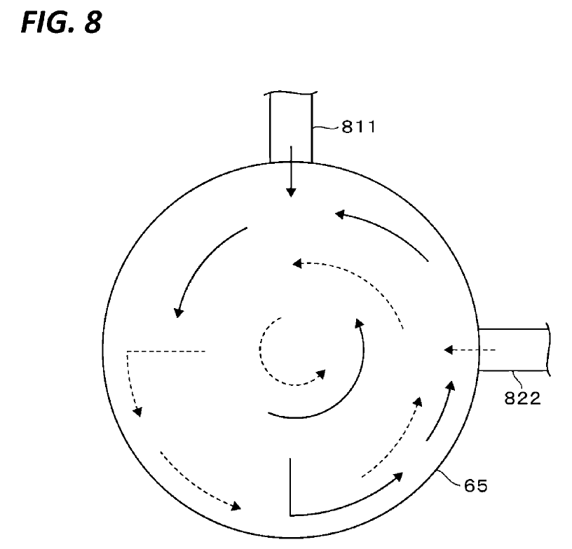

A downstream end of the second supply path 822 is connected to the mixing section 65 from a lateral side, similarly to the downstream end of the first supply path 811, and a position at which the downstream end of the second supply path 822 is connected differs from a position at which the downstream end of the first supply path 811 is connected, in the circumferential direction of the mixing section 65. In a schematic plan view of the mixing section 65 illustrated in FIG. 8, the first gas supplied from the first supply path 811 is indicated by solid arrows, and the second gas supplied from the second supply path 822 is indicated by dashed arrows.

As described above, the first gas and the second gas supplied to different positions in the circumferential direction of the mixing section 65 significantly interfere with each other due to being introduced from different positions. In addition, each gas flows along a wall surface defining the mixing section 65, for example, in a swirling manner. Therefore, the gases are sufficiently agitated and are favorably mixed. Then, since the mixing section 65 has a relatively small diameter and thus defines a space having a relatively small volume, the first gas and the second gas are agitated in a state where excessive diffusion is suppressed, thereby promoting more reliable mixing. Since the first gas and the second gas are supplied laterally into the mixing section 65, the residence time before reaching the diffusion space 631 is longer than in a case where the gases are supplied downward into the mixing section 65, which further ensures effective mixing. In this way, the first gas and the second gas, sufficiently mixed in the mixing section 65, flow into the diffusion space 631 having a relatively large volume and are discharged from the discharge ports 632 toward the wafer W. Therefore, processing proceeds with high in-plane uniformity on the wafer W.

In addition, the apparatus may be configured such that the first gas and the second gas are directly supplied to the diffusion space 631 and mixed therein. However, since the diffusion space 631 has a relatively large volume, there is a concern that sufficient mixing may not occur before the respective gases are supplied into the processing space 60. Therefore, it is desirable to adopt a configuration in which the gases mixed in the mixing section 65 are supplied to the diffusion space 631. For the convenience of description, the first gas and the second gas mixed in the mixing section 65 may hereinafter be referred to as a reaction gas.

### Other Exhaust Paths in Processing Container

The processing container 61 will be described in more detail. As illustrated in FIGS. 5 and 7, a plurality of central exhaust ports 671 and a plurality of peripheral exhaust ports 681 are formed in the lower surface of the ceiling plate 63 at positions that do not interfere with the discharge ports 632. For example, the central exhaust ports 671 are provided in the vicinity of the mixing section 65 at intervals in the circumferential direction, and open downward toward a central portion of the processing space 60. These central exhaust ports 671 form upstream ends of central exhaust paths 672 formed in the inside of the ceiling plate 63, and downstream sides of the respective central exhaust paths 672 merge together to form a junction path. This junction path opens into the protrusion 66 of the processing container 61 and is connected to an exhaust mechanism 67 via an exhaust path 673 provided outside the processing container 61. In addition, in FIG. 5, reference numeral 674 denotes a partition wall provided to partition the central exhaust paths 672 from the diffusion space 631.

Further, as illustrated in FIGS. 5 and 7, for example, the peripheral exhaust ports 681 are formed outside a region, in which the discharge ports 632 are formed, at intervals in the circumferential direction, and open downward toward a peripheral edge portion of the processing space 60. More specifically, in a plan view, the peripheral exhaust ports 681 are positioned so as to face the exhaust unit 64 located at the outer periphery of the hot plate 62, and therefore, do not overlap the placement region of the wafer W. Accordingly, the peripheral exhaust ports 681 are provided laterally with respect to the placement region. Then, the respective peripheral exhaust ports 681 form upstream ends of peripheral exhaust paths 682 provided in the inside of the ceiling plate 63, and downstream sides of the respective peripheral exhaust paths 682 extend toward a central portion of the ceiling plate 63 and merge there to form a junction path. This junction path opens into the protrusion 66 of the processing container 61 and is connected to an exhaust mechanism 68 via an exhaust path 683 provided outside the processing container 61.

The exhaust mechanisms 67 and 68 each include a valve, for example. The processing space 60 may be exhausted from the central exhaust ports 671 by opening the valve of the exhaust mechanism 67 and may be exhausted from the peripheral exhaust ports 681 by opening the valve of the exhaust mechanism 68. In this way, although the processing space 60 of the processing container 61 may be exhausted not only through the above-described exhaust ports 641 but also through outer exhaust ports, an example in which the wafer W is processed through exhaust from the central exhaust ports 671 and the peripheral exhaust ports 681 will be described below. In the present embodiment, however, it is assumed that the wafer W is processed through exhaust from the exhaust ports 641.

In addition, the central exhaust ports 671 and the peripheral exhaust ports 681 are formed relatively large in order to enhance exhaust efficiency of the processing space 60. In contrast, the discharge ports 632 are formed relatively numerous and small in order to suppress variations in the amount of processing gas supplied to respective portions in the plane of the wafer W. Therefore, for example, when the central exhaust ports 671, the peripheral exhaust ports 681, and the discharge ports 632 are each circular, the diameter of the discharge ports 632 is smaller than those of the central exhaust ports 671 and the peripheral exhaust ports 681. From another perspective, establishing such a relationship between the diameters contributes to achieving high in-plane uniformity of processing on the wafer W by the processing gas and to promptly removing the processing gas after processing, thereby improving apparatus throughput.

As described above, the opening 611 is formed in the front sidewall of the processing container 61 formed as described above, so as to be opened and closed by the shutter 612. The opening 611 is formed in a rectangular shape, for example, when viewed from the front side, and the shutter 612 is shaped to close the opening 611 and is provided with a sealing member 614 at a position corresponding to the sidewall of the processing container 61 around the opening 611. The shutter 612 is provided so as to be movable in the front-rear direction and the vertical direction by a drive mechanism 615, and is configured, for example, to move first forward and then downward when opening the opening 611.

### Temperature Control Unit

Next, the temperature control unit 56 illustrated in FIG. 4 will be described. The temperature control unit 56 includes a plate-shaped temperature adjustment plate 57 on which the wafer W is placed, and has functions of transferring the wafer W between the wafer transport device 33 and the hot plate 62 and adjusting the temperature of the wafer W. The temperature adjustment plate 57 has a flow path (not illustrated) through which a temperature-adjusted fluid flows, and the wafer W placed on the temperature adjustment plate 57 is temperature-adjusted by heat exchange with the fluid. Further, the temperature adjustment plate 57 is formed with a slit (not illustrated) extending in the front-rear direction, and is configured to enable transfer of the wafer W to and from the lifting pin 622 of the hot plate 62. The temperature adjustment plate 57 is configured to be movable in the front-rear direction by a drive mechanism 58 via a support arm 581 provided on a lower surface at a front side thereof.

### Dilution Gas

As described above, the gas supply chamber 53 is formed in the ceiling wall of the case 51. The gas supply chamber 53 is configured, for example, as a flat space provided in the inside of the ceiling wall. A large number of gas discharge ports 531, each connected to the gas supply chamber 53, are formed in a distributed manner on a lower surface of the ceiling wall. A dilution gas is supplied to the gas supply chamber 53 from a dilution gas supply source 86 through a dilution gas supply path 861. As the dilution gas, for example, an inert gas is used, and more specifically, an N₂ gas is used. In this way, the dilution gas supplied to the gas supply chamber 53 is discharged from the gas discharge ports 531 into the case 51 above the heat treatment section 6 and the temperature control unit 56.

Further, a downstream end of a dilution gas supply path 862, an upstream side of which is connected to the dilution gas supply source 86, is connected to a portion of the exhaust path forming member 643 located outside the case 51. The exhaust path forming member 643 extends from the exhaust ports 641 provided around the hot plate 62 to the first exhaust duct 71 in order to exhaust the processing space 60 as described above. Thus, the dilution gas is supplied from the supply source 86 into the exhaust path 642 in the exhaust path forming member 643. In addition, the exhaust ports 641 correspond to a first exhaust port, and the first exhaust duct 71 corresponds to a first exhaust path formation portion provided outside the heat treatment apparatus. Then, the exhaust path 642 corresponds to an exhaust flow path connecting the first exhaust port and the first exhaust path formation portion, and the dilution gas supply path 862 is connected to the exhaust flow path.

Such a dilution gas is supplied, for example, when a gas having combustion supporting properties such as an O₂ gas, a toxic gas such as an ammonia gas, or a corrosive gas such as a carboxylic acid is used as the processing gas, in order to dilute these gases and enhance safety. More specifically, the dilution gas supplied from the ceiling of the case 51 lowers the concentration of the processing gas in the case 51 even if the processing gas leaks from inside the processing container 61 to the outside of the processing container 61, thereby enhancing safety. Further, the dilution gas is supplied into the exhaust path 642 of the exhaust path forming member 643 in order to reduce the concentration of the processing gas and to be directed to the first exhaust duct 71 in a state of enhanced safety.

The supply of the dilution gas from the ceiling of the case 51 and the supply of the dilution gas to the exhaust path 642 are, for example, continuously performed while the heat treatment apparatus 5 is in operation. In addition, although the dilution gas is supplied to a portion of the exhaust path 642 located outside the case 51, the downstream end of the dilution gas supply path 862 may instead be connected to the exhaust path forming member 643 or to the exhaust unit 64 such that the dilution gas is supplied to a portion of the exhaust path 642 located inside the case 51 or to the exhaust path 640 in the exhaust unit 64. Thus, dilution may be performed at a position closer to the exhaust ports 641, thereby further enhancing safety.

### Exhaust Chamber

The horizontal partition plate 551 is provided below the hot plate 62 in the case 51, and a space below the partition plate 551 is formed as the exhaust chamber 55 partitioned from a space above the partition plate 551. Accordingly, the exhaust chamber 55 is a space partitioned from the processing space 60. In addition, in the following description, a region above the partition plate 551 is referred to as a wafer transport chamber 59 in which the wafer W is transported by the above-described temperature control unit 56. The dilution gas supplied from the ceiling of the case 11 described above is supplied to the wafer transport chamber 59. In addition, the partition plate 551 is formed with a plurality of exhaust ports 552, through which a portion of the dilution gas supplied from the ceiling of the case 51 enters the exhaust chamber 55.

The exhaust chamber 55 is also partitioned from the region 50, in which the drive mechanism 522 for the shutter 521 of the case 51 is accommodated, by a partition wall 540 provided in the case 51, and is located at the rear of the region 50. The exhaust chamber 55 is formed to be elongated in the front-rear direction as a drive region in which the above-described respective drive mechanisms are located. For example, the drive mechanism 625 for the lifting pin 622, the drive mechanism 615 for the shutter 612 of the processing container 61, and the drive mechanism 58 for the temperature adjustment plate 57 are arranged side by side in this order from the rear to the front in an upper side of the exhaust chamber 55. Accordingly, these drive mechanisms are arranged in the longitudinal direction of the exhaust chamber 55. In addition, these drive mechanisms 625, 615, and 58 may include, for example, an air cylinder, a motor, a drive belt, and/or a drive gear.

An exhaust path forming member 54 such as a duct elongated in the front-rear direction is disposed at the bottom of the exhaust chamber 55, and an exhaust path 543 is formed in the inside of the exhaust path forming member 54. A plurality of exhaust chamber exhaust ports 541 are provided in an upper surface of the exhaust path forming member 54 and open into the exhaust chamber 55, respectively. The exhaust chamber exhaust ports 541, each of which opens upward as described above, are arranged, for example, at intervals in the longitudinal direction of the exhaust path forming member 54. A front-end exhaust port 542 is provided at a front end of the exhaust path forming member 54, and opens into the region 50 through a hole formed in the partition wall 540. In addition, each of the exhaust chamber exhaust ports 541 and the front-end exhaust port 542 communicates with the exhaust path 543 in the exhaust path forming member 54.

Then, the second exhaust duct 72 described with reference to FIG. 3 is connected to the case 51 at a position between the case 51 and the first exhaust duct 71 described above, and a rear end of the exhaust path 543 in the exhaust path forming member 54 communicates with the second exhaust duct 72 through a hole 721 provided in the case 51. Accordingly, the exhaust chamber 55 is exhausted through the exhaust chamber exhaust ports 541, and the region 50 is exhausted through the front-end exhaust port 542. The gases from the exhaust chamber exhaust ports 541 and the front-end exhaust port 542 are introduced into the second exhaust duct 72, which serves as a second exhaust path formation portion. By the exhaust chamber exhausts port 541 and the front-end exhaust port 542, exhaust toward the second exhaust duct 72, which is separate from the first exhaust duct 71 provided for exhausting the processing space 60, is performed. Then, such exhaust toward the second exhaust duct 72 suppresses particles generated from the respective drive mechanisms 625, 615, and 58 in the exhaust chamber 55 and from the drive mechanism 522 in the region 50 from flowing into the wafer transport chamber 59 and contaminating the wafer W.

The arrangement of the exhaust chamber exhaust ports 541 of the exhaust path forming member 54 will be described in supplementary detail. The exhaust chamber exhaust ports 541, which correspond to a second exhaust port, opens at a lower side in the exhaust chamber 55. The lower side in the exhaust chamber 55 refers to a lower half region when the exhaust chamber 55 is divided equally to an upper region and a lower region in the height direction. When a plurality of exhaust chamber exhaust ports 541 are provided as in the present embodiment, it is sufficient that at least one of them is located in the lower half region. By providing the exhaust chamber exhaust ports 541 at a relatively low position in the exhaust chamber 55, a vertical range in which a suction effect from the exhaust chamber exhaust ports 541 is relatively strong is increased, thereby more reliably guiding and removing particles emitted from the respective drive mechanisms 625, 615, and 58 into the exhaust chamber exhaust ports 541. In addition, although the exhaust chamber exhaust ports 541 may open laterally, in order to exhaust a region above the height at which the exhaust chamber exhaust ports 541 are located, it is desirable that they open upward. Further, instead of providing the plurality of exhaust chamber exhaust ports 541 as described above, a single slit extending from the front to the rear in the exhaust chamber 55 may be formed.

### Exhaust of Wafer Transport Chamber and Exhaust of Processing Space

The above-described third exhaust duct 73 is provided at a rear side of the wafer transport chamber 59 outside the case 51, and the wafer transport chamber 59 communicates with the third exhaust duct 73 through an exhaust port 731 provided in the case 51. Accordingly, the dilution gas supplied from the ceiling of the case 51 into the wafer transport chamber 59 is discharged into the third exhaust duct 73. In addition, a portion of the dilution gas supplied from the ceiling also flows into the exhaust chamber 55 and is discharged from the exhaust chamber exhaust ports 541.

The third exhaust duct 73 may be omitted since the gas in the wafer transport chamber 59 may be discharged from the exhaust chamber 55. However, if the processing gas leaks from the processing container 61, exhaust through the third exhaust duct 73 may suppress inflow of the processing gas into the exhaust chamber 55, thereby suppressing damage to or deterioration of members constituting the drive mechanisms 625, 615, and 58 due to the processing gas. Therefore, it is desirable to perform exhaust through the third exhaust duct 73.

However, since the gas in the processing space 60 is discharged to the first exhaust duct 71 as described above, exhaust through the first exhaust duct, which is separate from the second exhaust duct 72 provided for exhausting the exhaust chamber 55 and the wafer transport chamber 59, is performed. Providing different exhaust destinations for the processing space 60 and for the exhaust chamber 55 and the wafer transport chamber 59 is advantageous in terms of apparatus flexibility, particularly when there is a requirement to exhaust a gas used as a processing gas to an exhaust destination different from that for an inert gas. Specifically, for example, when an exhaust source of an exhaust destination by the second exhaust duct 72 includes equipment such as a fan and the processing gas is corrosive to such equipment, discharging the processing gas through the first exhaust duct 71 suppresses corrosion of that equipment due to the processing gas, which is desirable.

### Operation of Heat treatment Apparatus

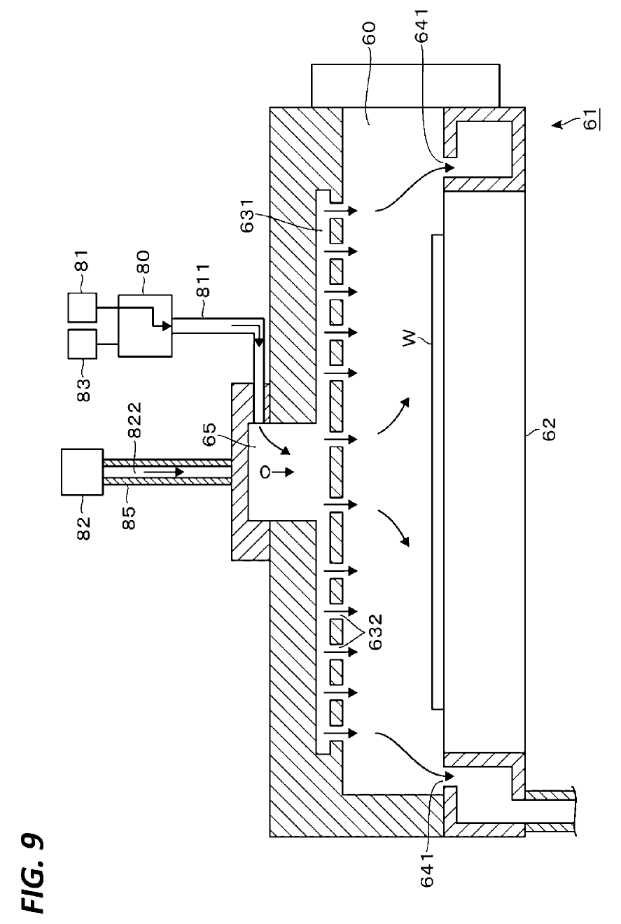

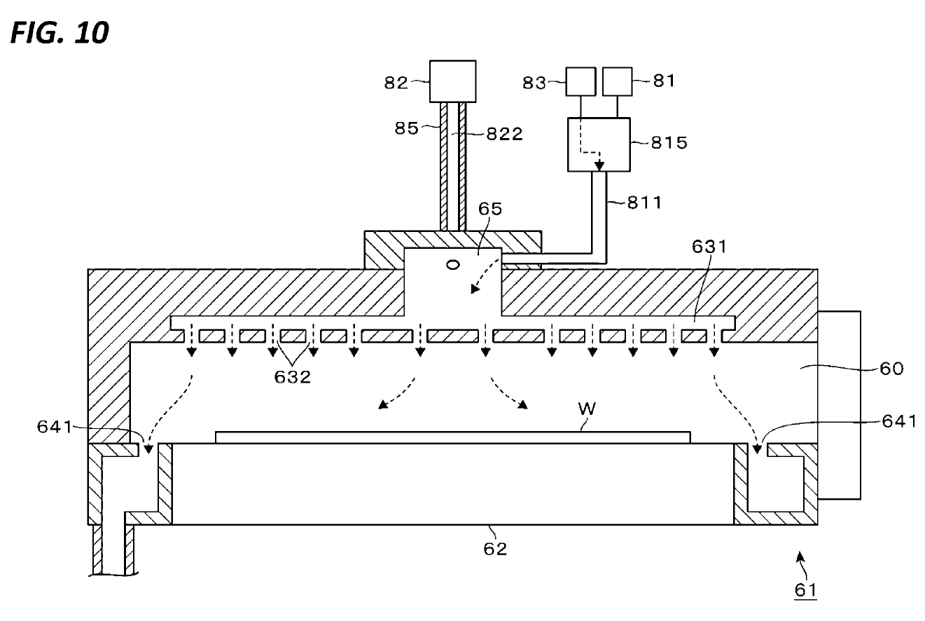

Next, processing of the wafer W performed in the heat treatment apparatus 5 will be described with reference to the longitudinal sectional side views of the processing container 61 illustrated in FIGS. 9 and 10. The wafer W transported to the heat treatment apparatus 5 by the wafer transport device 33 is sequentially transferred to the temperature control unit 56 and the lifting pin 622, and is placed on the hot plate 62 by lowering the lifting pin 622, where it is heated to a predetermined temperature, while the processing container 61 is closed by the shutter 612.

In a state where the processing space 60 is exhausted through the exhaust ports 641, the first gas and the second gas are supplied from the first gas supply unit 80 and the second gas supply unit 82, respectively, toward the mixing section 65. As described above, in this example, the first gas is the first processing gas supplied from the supply source 81. The second gas is a mixed gas of the second processing gas and a carrier gas (inert gas) for the second processing gas, and is supplied to the mixing section 65 in a heated state by the heating unit 85. As described above with reference to FIG. 8, the first and second gases are mixed in the mixing section 65 to form a reaction gas. The reaction gas is discharged from the discharge ports 632 through the diffusion space 631 and supplied over the entire surface of the heated wafer W, thereby processing the wafer W (e.g., FIG. 9). The reaction gas supplied to the wafer W in this manner flows toward a circumferential edge of the wafer W while acting on the wafer W under exhaust through the exhaust ports 641, and then removed from the exhaust ports 641.

Subsequently, the supply of the first gas and the second gas from the first gas supply unit 80 and the second gas supply unit 82 to the mixing section 65 is stopped, thereby completing processing of the wafer W. Then, the first gas supply unit 80 supplies the inert gas from the second gas supply 83 to the mixing section 65 as a purge gas instead of the first gas, and the inert gas is discharged from the discharge ports 632 through the diffusion space 631. The inert gas flows toward the exhaust ports 641, similarly to the reaction gas, and pushes out the reaction gas remaining in the processing space 60 to remove it from the processing space 60 (see, e.g., FIG. 10). Thereafter, the supply of the purge gas from the first gas supply unit 80 is stopped, and the wafer W is unloaded from the processing container 61 by an operation reverse to that performed during loading into the processing container 61, and is transferred to the wafer transport device 33.

However, although the purpose of heating the second processing gas by the heating unit 85 has been described as suppressing liquefaction of the second processing gas contained in the second gas, the heating is not limited to this liquefaction suppression purpose. For example, the heating may be performed in order to enhance reactivity of the first processing gas in the first gas with respect to a film on the wafer W by heating the first processing gas with heat of the second gas during mixing in the mixing section 65. To this end, the temperature of the second gas supplied to the mixing section 65 is set higher than the temperature of the first gas supplied to the mixing section 65. That is, heating by the heating unit 85 is performed such that the temperature of the second gas in the second supply path 822 is higher than the temperature of the first gas in the first supply path 811 (e.g., such that a temperature difference is formed between the first processing gas and the second processing gas before mixing).

In addition, the first supply path 811 through which the first gas flows may also be provided with a heating unit, which corresponds to the heating unit 85 of the second supply path 822, to heat the first gas. However, utilizing the temperature difference between the first gas and the second gas, formed by the heating unit 85 in the second supply path 822, to heat the first gas is advantageous in simplifying the apparatus configuration.

### Another Processing Operation Example

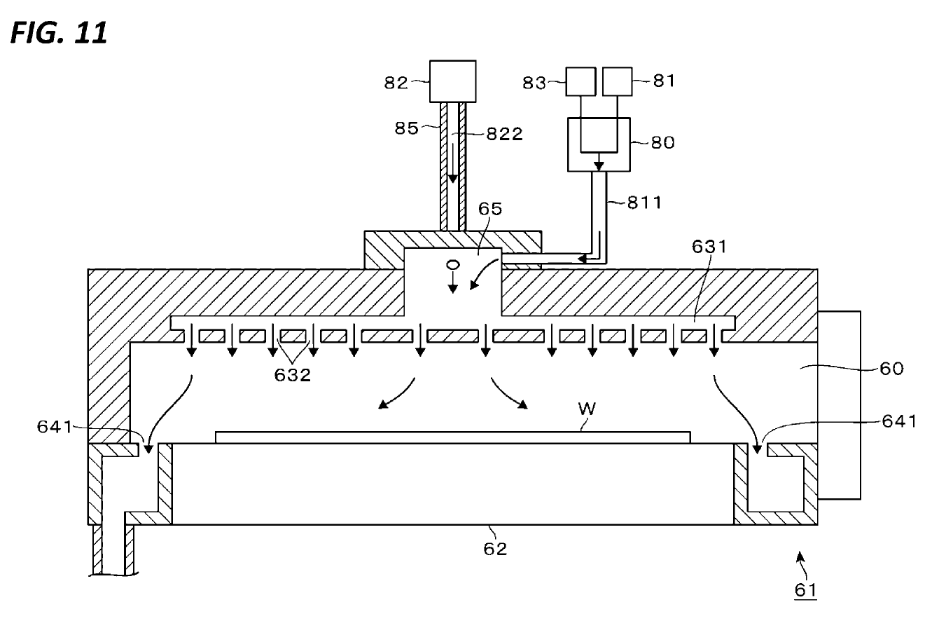

Although FIG. 9 illustrates an example in which the first processing gas is supplied alone as the first gas to the mixing section 65, as illustrated in FIG. 11, the first processing gas and the inert gas may be supplied from the supply sources 81 and 83, respectively, to the first gas supply unit 80, and a mixed gas thereof may be supplied as the first gas to the mixing section 65. That is, the mixed gas serving as the first gas and the above-described second gas may be mixed in the mixing section 65 to form a reaction gas, and this reaction gas may be supplied to the processing space 60, thereby processing the wafer W.

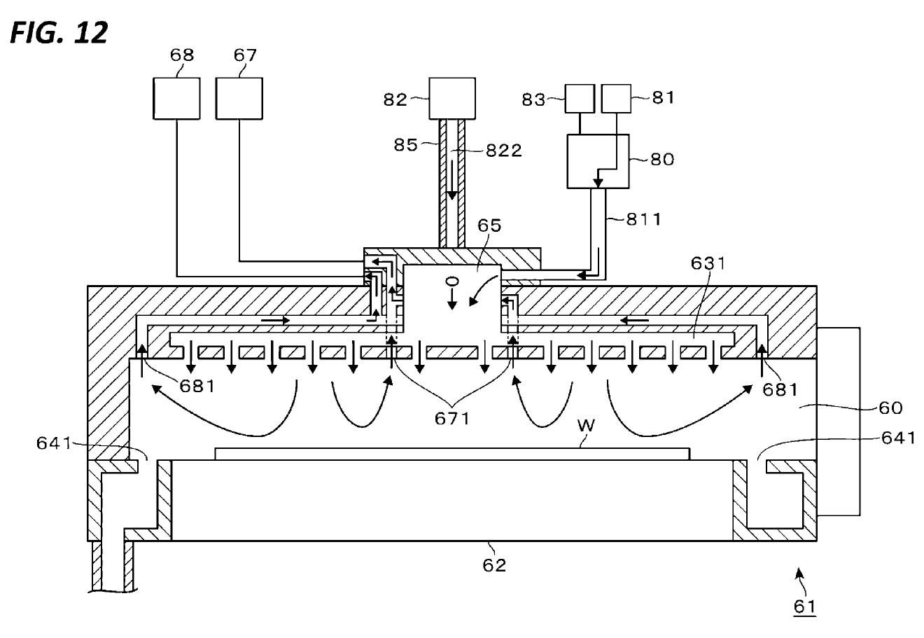

Further, as described above, exhaust of the processing space 60 is not limited to being performed through the exhaust ports 641 provided around the hot plate 62. FIG. 12 illustrates an example in which, when the wafer W is processed by supplying the reaction gas to the processing space 60 as described above with reference to FIG. 9, exhaust is performed not through the exhaust ports 641 but through the central exhaust ports 671 and the peripheral exhaust ports 681 of the ceiling plate of the processing container 61. In such a case where the processing space 60 is exhausted through the central exhaust ports 671 and the peripheral exhaust ports 681, exhaust through the exhaust ports 641 may be unnecessary. Therefore, the exhaust ports 641 may be omitted. Further, a valve for opening and closing the exhaust paths 642 that connect the exhaust ports 641 and the first exhaust duct 71 may be provided in the exhaust path forming member 643, and exhaust through the exhaust ports 641 may be suppressed by closing this valve.

In addition, although FIG. 12 illustrates that exhaust of the processing space 60 through the central exhaust ports 671 and the peripheral exhaust ports 681 is performed during supply of the reaction gas to the wafer W, exhaust through the central exhaust ports 671 and the peripheral exhaust ports 681 may also be performed, instead of exhaust through the exhaust ports 641, during purge of the reaction gas described above with reference to FIG. 10. Then, although FIG. 12 illustrates an example in which the processing space 60 is exhausted through both the central exhaust ports 671 and the peripheral exhaust ports 681, exhaust of the processing space 60 may be performed through only one of the central exhaust ports 671 and the peripheral exhaust ports 681 during supply of the reaction gas to the wafer W and/or during purge of the reaction gas. In addition, as illustrated in FIGS. 9-11, when exhaust is performed through the exhaust ports 641 provided around the hot plate 62, exhaust through the central exhaust ports 671 may also be performed simultaneously with exhaust through the exhaust ports 641.

As described above, exhaust through exhaust ports arranged on the outer periphery of the placement region of the wafer W may be performed as downward exhaust as exemplified by a case using the exhaust ports 641, or may be performed as upward exhaust as exemplified by a case using the peripheral exhaust ports 681. In order to enhance exhaust efficiency in performing exhaust through the exhaust ports arranged on the outer periphery, exhaust may also be performed through exhaust ports arranged on a central portion of the wafer W as exemplified by a case using the central exhaust ports 671.

### Other Configuration Example of Heat Treatment Apparatus

The first gas supply unit 80 may be configured in the same manner as the second gas supply unit 82. That is, the first gas supply unit 80 may be configured such that a liquid is vaporized to generate a first processing gas, and the first processing gas is supplied together with a carrier gas to the mixing section 65 of the processing container 61. Conversely, the second gas supply unit 82 may be configured in the same manner as the first gas supply unit 80. That is, a mixed gas of a second processing gas and an inert gas serving as both a carrier gas and a dilution gas may be supplied to the mixing section 65. Further, a plurality of first gas supplies unit 80 and/or second gas supplies unit 82 may be provided, and different processing gases may be supplied from the respective gas supplies to the mixing section, such that three or more types of processing gases are mixed in the mixing section 65 and supplied to the processing space 60. Further, although the processing container 61 is opened and closed by operation of the shutter 612 in the above-described configuration example of the heat treatment apparatus 5, the opening/closing mechanism is not limited to such an apparatus configuration. For example, the ceiling plate of the processing container 61 may serve as a lid, and a portion of the processing container 61 other than the ceiling plate may serve as a container body, with the lid connected to a lifting mechanism. The lifting mechanism may raise and lower the lid relative to the container body to open and close the processing container 61.

In each embodiment, a substrate as a processing target is not limited to a wafer, and may be, for example, a substrate for manufacturing a flat panel display or a mask substrate for manufacturing an exposure mask. Accordingly, a rectangular substrate may also be processed.

The present disclosure is capable of performing heat treatment on a substrate in an atmosphere including a desired gas.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A heat treatment apparatus comprising:
a processing container having a processing space formed therein;
a stage on which a substrate is placed to face the processing space;
a heater configured to heat the substrate placed on the stage;
a discharge port that is open to the processing space and configured to discharge a processing gas to the substrate heated by the heater; and
a mixing section forming a gas supply path connected to the discharge port and configured to mix gases such that two or more types of processing gases and a carrier gas for each of the two or more types of processing gases are brought into a mixed state.

2. The heat treatment apparatus according to claim 1, wherein at least one processing gas among the two or more types of processing gases is supplied to the mixing section in a state mixed with the carrier gas.

3. The heat treatment apparatus according to claim 2, wherein a plurality of discharge ports are provided,
a diffusion space is provided to diffuse and distribute the processing gases to each of the plurality of discharge ports, and
the mixing section is connected to the diffusion space.

4. The heat treatment apparatus according to claim 3, further comprising:
a gas heater configured to heat a portion of the supply path upstream of the mixing section and to form a temperature difference among the two or more types of processing gases before mixing.

5. The heat treatment apparatus according to claim 1, further comprising:
a mixer configured to mix one processing gas among the two or more types of processing gases and the carrier gas before being supplied to the mixing section,
wherein the processing container and the mixer are provided in a same layer among a plurality of layers that are stacked and partitioned with each other and in each of which the substrate is transferred.

6. The heat treatment apparatus according to claim 1, wherein the discharge port is provided in a ceiling of the processing container and opens downward, and
an exhaust port is formed laterally with respect to a placement region of the substrate on the stage, and opens upward to exhaust the processing space.

7. The heat treatment apparatus according to claim 1, wherein the discharge port is provided in a ceiling of the processing container and opens downward, and
an exhaust port is formed laterally with respect to a placement region of the substrate on the stage, and opens downward to exhaust the processing space.

8. The heat treatment apparatus according to claim 1, further comprising:
a first exhaust port formed laterally with respect to a placement region of the substrate on the stage and configured to exhaust the processing space toward a first exhaust path formation portion provided outside the heat treatment apparatus;
an exhaust flow path connecting the first exhaust port and the first exhaust path formation portion; and
a dilution gas supply path connected to the exhaust flow path to dilute a gas flowing through the exhaust flow path.

9. The heat treatment apparatus according to claim 1, further comprising:
a drive region provided below the processing space and partitioned from the processing space, the drive region accommodating a drive mechanism configured to move a component provided in the heat treatment apparatus; and
a second exhaust port provided below the drive region and configured to exhaust the drive region.

10. The heat treatment apparatus according to claim 9, wherein a first exhaust port is provided in the processing container and configured to exhaust the processing space toward a first exhaust path formation portion provided outside the heat treatment apparatus, and
the second exhaust port is configured to exhaust a gas toward a second exhaust path formation portion provided separately from the first exhaust path formation portion.

11. A heat treatment method comprising:
transporting a substrate into a processing space formed inside a processing container;
placing the substrate on a stage to face the processing space;
heating the substrate placed on the stage by a heater;
discharging a processing gas to the substrate heated by the heater from a discharge port that is open to the processing space; and
mixing gases in a mixing section forming a gas supply path connected to the discharge port, such that two or more types of processing gases and a carrier gas for each of the two or more types of processing gases are brought into a mixed state.
